(19) United States
(12) Patent Application Publication
(10) Pub. No.: US 2002/0016012 A1
(43) Pub. Date: Feb. 7, 2002

(54) Precise local creation of openings in a layer

(76) Inventors: Matthias Kronke, Dresden (DE); Gunther Schindler, Munchen (DE)

Correspondence Address: LERNER AND GREENBERG, P.A., PATENT ATTORNEYS AND ATTORNEYS AT LAW, Post Office Box 2480, Hollywood, FL, 33022-2480, US

(21) Appl. No.: 09/881,431

(22) Filed: Jun. 14, 2001

(30) Foreign Application Priority Data
Jun. 14, 2000 (DE) 100 29 290.9

(51) Int. Cl. H01L 21/00; H01L 21/44

(52) U.S. Cl. 438/3; 438/667

(57) ABSTRACT

A method for the precise local creation of openings in a layer, particularly a protective layer on a microelectronic structure is described. A raised auxiliary structure is applied to a substrate such that a part of the surface of the substrate is covered. The layer to be opened is applied to the auxiliary structure and by planar etching of the material of the layer and possibly additional material is removed until the layer at the auxiliary structure is opened and the auxiliary material is exposed.

### BACKGROUND OF THE INVENTION

1. Field of the Invention

The invention concerns a method for the precise local creation of openings in a layer, particularly in a protective layer on microelectronic structures. The invention concerns in particular a method for fabricating a non-volatile memory cell for storing binary data. Memory cells of this kind usually have a switching transistor and a storage capacitor. The capacitor electrodes can contain a platinum metal, between which a ferroelectric or paraelectric material is disposed as a dielectric.

Conventional microelectronic semiconductor memory components (DRAMs) are formed essentially of a selecting or switching transistor and a storage capacitor in which a dielectric material is inserted between two capacitor plates. Usually, the dielectric material mostly used contains oxide or nitride layers that have a dielectric constant of approximately 8 at the most. In order to reduce the size of the storage capacitor and for the fabrication of non-volatile memories, “novel” capacitor materials (ferroelectrics or paraelectrics) are needed with significantly higher dielectric constants. Examples of such materials are named in the publication “Neue Dielektrika für Gbit-Speicherchips” [New Dielectrics for Gbit Memory Chips] by W. Honlein, Phys. Bl. 55 (1999). For the fabrication of ferroelectric capacitors for use in non-volatile semiconductor memory components of high integration density it is possible to use, for example, ferroelectric materials such as SrBi₂(Ta,Nb)₂O₉ (SBT or SBTN), Pb(Zr, Ti)O₃ (PZT) or Bi₄Ti₃O₁₂ (BTO) as the dielectric between the plates of the capacitor. However, it is also possible to use a paraelectric material such as (Ba,Sr)TiO₃ (BST).

However, the use of these novel kinds of dielectric presents new challenges for semiconductor process technology. First, these novel materials can no longer be combined with the traditional electrode material polycrystalline silicon. It is therefore necessary to use inert electrode materials, for example platinum metals or their conductive oxides (e.g. RuO₂)The reason for this is that after deposition of the ferroelectric, this must be tempered (“conditioned”) several times in an atmosphere containing oxygen at temperatures in the region of 550-800° C. In order to avoid unwanted chemical reactions between the ferroelectric and the electrodes, these are therefore mostly made of platinum or some other adequately temperature resistant and inert material such as a different platinum metal (Pd, Ir, Rh, Ru, Os).

For integration of the storage capacitors process steps are performed which take place in an environment containing hydrogen. Thus, for example, conditioning the metallization and the transistors must be performed by tempering in forming gas, which consists of 95% nitrogen (N₂) and 5% hydrogen (H₂). Penetration of hydrogen into the processed storage capacitor, i.e. into the dielectric, can, however, lead to degradation of the oxide ceramic materials of the dielectric as a result of reduction reactions. Moreover, the plasma-enhanced deposition of intermetal oxides (PECVD) or the silicon nitride passivation layer can effect reduction of the ferroelectric or paraelectric material of the dielectric as a result of the high concentration of hydrogen in the layers. Hydrogen is also used during the deposition of electrically conductive materials such as refractory metals like tungsten or titanium. Deposition is used, for example, for the generation of layers or for filling contact holes.

In order to protect the capacitors and their dielectrics from hydrogen, a protective layer is suggested as a barrier against the penetration of hydrogen into the capacitor. The protective layer consists, for example, of oxide materials such as Al₂O₃, ZrO₂ or TiON and is applied, for example, directly to the capacitor structure.

In order to provide electrical contacts between microelectronic structural components it is usual—after fabrication of the actual structure and, if necessary, after the attachment of further materials to the structure—to etch contact holes and to fill these with electrically conductive material. If forming the electrical contact must be done from the side carrying the protective layer, the layer must be opened.

The creation of contact holes using a reactive ion etching (RIE) method is known from the prior art. RIE is a chemico-physical dry etching method. In order to be able to create the holes precisely, resist masks are used in the process.

Although it is possible to etch with high local precision using the method, the etching rates are low, especially with Al₂O₃ and ZrO₂. The problem of etching contact holes using the methods of the prior art such as RIE is further exacerbated by the fact that it is necessary first to etch through a material normally lying above the protective layer (mostly SiO₂). The protective layer is then reached after etching has progressed accordingly. The etching material (which is already intrinsically difficult to etch) at the bottom of a hole—in this case the upper part of the contact hole—is particularly difficult, i.e. particularly slow and frequently inaccurate.

In addition, the selectivity between different materials is low, i.e. the method also leads as a rule to removal of the material of the resist masks and/or to the removal of electrode material at the bottom of the contact hole. If ions arrive at an angle on the surface to be etched, in other words if the ions do not strike the surface perpendicularly, reflections can occur at sloping sides of the etched site. This leads to the formation of unwanted trenches or holes at the edge of the etched site or on the floor of the etched hole (so-called trench effect). Moreover, the impact of the ions, which possess a high kinetic energy in RIE, can cause damage to the surface to be etched. Finally, RIE is also prone to so-called redeposition, i.e. material which has been removed is redeposited in a different location.

Especially when the integrity of the layer to be opened is important, as in the case of the above protective layers against the penetration of hydrogen, the effects described can exert a negative influence on the function of the layer and/or on the function of the microelectronic structure. For example, lateral trenches at the bottom of the etched opening can later lead to infiltration of the hydrogen barrier by hydrogen molecules.

### SUMMARY OF THE INVENTION

It is accordingly an object of the invention to provide a precise local creation of openings in a layer which overcomes the above-mentioned disadvantages of the prior art methods of this general type, in which precise, local opening is possible of the layer to be opened, whereby the layer to be opened should remain as undamaged as possible outside the actual area of the opening. With the foregoing and other objects in view there is provided, in accordance with the invention, a method for precise local creation of openings in a structure. The method includes the steps of providing a substrate, producing at least one raised auxiliary structure formed of an auxiliary material on the substrate such that the auxiliary structure covers a part of a surface of the substrate, applying a layer, in which an opening is to be formed, to the auxiliary structure such that the layer covers a continuous region of the surface of the substrate and a surface of the auxiliary structure, and using a planar etching process for removing part of a material forming the layer until the layer at the auxiliary structure is opened and the auxiliary material is exposed resulting in exposed auxiliary material.

In the method according to the invention at least one raised auxiliary structure formed of the auxiliary material is applied to the substrate, possibly with structures already attached, such that the auxiliary structure covers a part of the surface of the substrate. In this case, the term substrate refers to a unit containing the actual substrate to which a microelectronic structure is attached, and the microelectronic structure itself. Further layers or components can be present which are allocated to the substrate.

The layer to be opened is applied to the auxiliary structure such that it covers a continuous area of the surface of the substrate and the auxiliary structure. Essentially planar etching is then used to remove a material of the layer and possibly other material on the surface, until the layer on the auxiliary structure is opened and the auxiliary material is exposed.

Planar etching is an etching process which removes material almost evenly at a level surface, or removes material at a surface in such a way that an essentially plane surface is produced. Thus as a result of the planar etching, just that material of the layer is removed which is on the raised auxiliary structure, and the material of the auxiliary structure (auxiliary material) is exposed. In contrast, the auxiliary material outside the raised area of the surface remains unaffected.

An essential advantage of the invention is that undesirable side effects, such as the trench effect and redeposition, do not occur when the layer is opened. Moreover, a sharp, precisely defined transition is created between the layer to be opened and the material of the auxiliary structure. The dimensions and the position of the transition are defined through the shape of the auxiliary structure and through the progress of the planar etching. However, the size of the opening in the layer can also be independent of the progress of the planar etching, namely if the layer at the edge of the raised auxiliary structure extends in a direction running perpendicularly to the etching plane. In this case only that material on the raised section of the auxiliary structure must be removed which specifically extends parallel to the etching plane.

In particular, the raised auxiliary structure is an island-like elevation. In this case the material of the layer is removed in such a manner that it forms a closed peripheral edge around the exposed auxiliary material. This embodiment of the method can especially be used to advantage if the intention is to provide an electrical contacting extending through the layer to be opened.

In a further embodiment of the method, a second auxiliary material is applied after the application of the layer to be opened, so that irregularities are at least partially compensated and that deeper-lying areas are at least partially filled out. The etching plane during planar etching is preferably approximately parallel to the direction of the surface of the second auxiliary material. The second auxiliary material, which can be formed of the same material as or a different material to the auxiliary material of the auxiliary structure, serves for the mechanical stabilization of the entire structure, in particular of the layer to be opened. In this way it is guaranteed that the removal of material is determined solely by the control of the process of planar etching. The second auxiliary material also provides permanent protection against outside influences for the material of the layer that is located outside the area to be opened.

The first and/or second auxiliary material is, in particular, an oxide material, for example SiO₂. However, any other suitable material can also be used. If the intention is to achieve electrical insulation through the first and/or second auxiliary material, any required dielectric materials can be used, e.g. also polymers such as polytetrafluoroethylene (PTFE). Some of these are characterized by especially high dielectric constants.

The planar etching is preferably performed, at least partly, by a chemical mechanical polishing (CMP) process. In this process of the prior art, which is known as a planarization method, the weighting of the process components can be adjusted according to requirements between chemically supported mechanical polishing, and chemical wet etching supported by mechanical influence. CMP normally involves the provision of a polishing table with a flexible pad to which a polishing material (slurry) is applied. The surface to be etched is pressed onto the pad so that a relative movement takes place between the surface and the pad. This can involve rotation of either the polishing table and/or the surface to be etched.

The slurry is preferably selected taking into account the respective properties of the material to be removed, whereby the intention is mostly to achieve the maximum rate of etching.

In the embodiment of the method in which the above second auxiliary material is applied in order to generate an essentially plane surface, it is preferred first to use a slurry optimized in respect of the second auxiliary material and then, after etching has progressed to an appropriate extent, to change over to a slurry optimized in respect of the layer to be opened. In doing this, and to the extent that this is required, a selectively higher rate of etching is also achieved at the material of the layer to be opened.

In a further embodiment of the method, an opening is etched in the exposed auxiliary material of the auxiliary structure, which opening serves in particular for the electrical contacting through the opened layer. Preferably this results in the generation of a closed peripheral edge, which is formed by the auxiliary material of the auxiliary structure. As a result, the opening is separated from the material of the layer to be opened. This has the advantage that the opened layer is mechanically stabilized. In addition, methods of the prior art for the creation of contact holes and similar openings can be used, for example RIE as described above. The auxiliary material of the auxiliary structure protects the opened layer and prevents unwanted removal of the material of the layer. In the particular case of an opening extending as far as an electrically conductive material, a further electrically conductive material can be inserted. The opening can also be extended as far as an opposite outside surface of the substrate and an additional electrical contacting effected after the opening has already been filled with electrically conductive material.

The method according to the invention is used with particular advantage with substrates having a microelectronic structure with a capacitor, the dielectric of which has a ferroelectric or paraelectric material. In such cases the layer to be opened functions in particular as a barrier to prevent the penetration of a substance into the microelectronic structure. For example, the dielectric is sensitive towards the penetration of hydrogen or towards contact with hydrogen and the layer to be opened forms a barrier against the penetration of hydrogen into the microelectronic structure, especially in the region of the dielectric.

In this embodiment particular importance is attached to ensuring that the layer to be opened outside the area to be opened does not suffer any damage. In the course of the progressive miniaturization of digital memory modules, it is of decisive importance that practicable process techniques are available which allow specific, precise production of such structures and do not endanger the permanent functionality of the structures. The invention provides a method that enables the precise creation of openings although, or even because, it enables material to be removed in a planar manner. The position of the opening is, in fact, determined, or at least partly determined, beforehand through the shape of the auxiliary structure. The shape of the auxiliary structure can be achieved with high precision by process techniques of the prior art. For example, known dry etching methods such as RIE are used. Damage to the layer to be opened later is excluded since at the time the auxiliary structure is structured the layer is not yet present.

In another embodiment of the invention, the layer to be opened is formed of an electrically conductive material, and after exposure of the auxiliary material, an electrically insulating material is applied to the remaining material of the layer to be opened.

Other features which are considered as characteristic for the invention are set forth in the appended claims.

Although the invention is illustrated and described herein as embodied in a precise local creation of openings in a layer, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a diagrammatic, sectional view of a substrate with two raised island-like auxiliary structures, whereby a surface of the substrate and the auxiliary structures are covered with a layer to be opened;

FIG. 2 is a sectional view after a second auxiliary material has been applied which essentially forms a plane surface;

FIG. 3 is a sectional view after planar etching was used to create openings in the layer to be opened; and

FIG. 4 is a sectional view after holes were generated for electrical contacting of the microelectronic structure.

### DESCRIPTION OF THE PREFERRED EMBODIMENTS

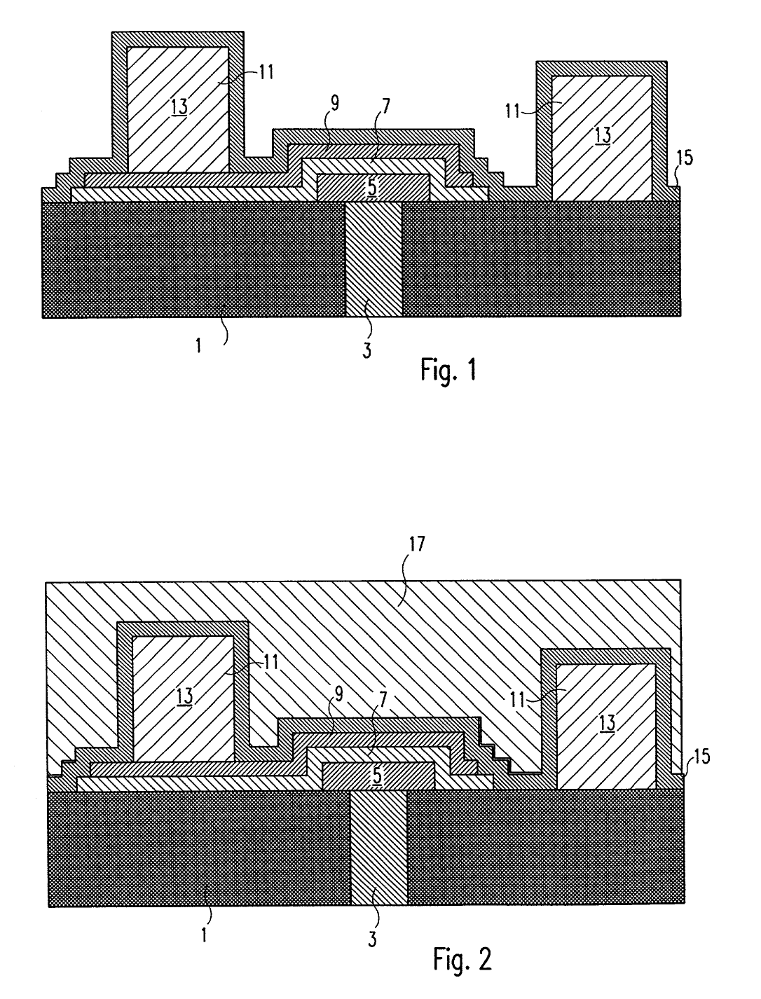

In all the figures of the drawing, sub-features and integral parts that correspond to one another bear the same reference symbol in each case. Referring now to the figures of the drawing in detail and first, particularly, to FIG. 1 thereof, there is shown a substrate material 1 as normally used in the fabrication of semiconductor components, for example crystalline silicon. An electrical connection 3 for electrically contacting and combining microelectronic structures is inserted in the substrate material 1. The electrical connection 3 contacts a first electrode 5 of an electrically conductive material, in particular of an inert material such as a platinum metal (Pt, Pd, Ir, Rh, Ru, Os).

A dielectric 7 of a ferroelectric or paraelectric material is applied to the first electrode 5. The dielectric material is especially sensitive towards contact with and/or the penetration of hydrogen.

To the dielectric 7 is applied a second electrode 9, which is formed of in particular of the same material as the first electrode 5. The two electrodes 5, 9 and the dielectric 7 jointly form a capacitor for storing digital information. The capacitor can be combined with a selecting or switching transistor in a manner of prior art in order to form a memory element (i.e. a dynamic random access memory (DRAM)). The transistor is located in particular in or below the substrate material 1 and is preferably connected electrically with the first electrode 5 through the electrical connection 3.

As shown in FIG. 1, an island 11 of an auxiliary material 13 is applied in the left-hand end region of the second electrode 9. A further island 11 of the auxiliary material 13 is applied directly on the surface of the substrate material 1. The auxiliary material 13 is, in particular, an oxide auxiliary material, for example SiO₂. The auxiliary material 13 can be deposited in a manner known in the prior art as a continuous, approximately equally high layer on the surface of the substrate 1. The island-like structure 11 illustrated in FIG. 1 can then be etched, also in a manner known in the prior art, for example using masks.

In the exemplary embodiment described by FIGS. 1 to 4, care must be taken that the islands 11 are raised above a level of the capacitor 5, 7, 9.

After structurization of the islands 11 a protective layer 15 to be opened is applied such that the entire surface of the substrate material 1, the capacitor 5, 7, 9 and the islands 11 are continuously covered on one side with the protective layer 15. The material of the protective layer 15 is, for example, an oxide material such as Al₂O₃, ZrO₂ or TiON. The protective layer 15 is formed of a suitable material and is sufficiently thick to prevent hydrogen penetrating through it. Thus the protective layer 15 is a barrier against the passage of hydrogen and protects the dielectric 7, which is sensitive towards hydrogen. In the horizontal direction (FIG. 1), seen from the edge of the islands, the protective layer 15 extends along the second electrode 9 and along the surface of the substrate material 1. Even if cavities are located at the material transition between the second electrode 9 and the protective layer 15, or between the substrate material 1 and the protective layer 15, the configuration described provides an effective barrier against the penetration of hydrogen into the capacitor 5, 7, 9, even if the hydrogen should penetrate into the region of the islands 11. For this purpose it is beneficial if in the exemplary embodiment the second electrode 9 and the substrate material 1 also provide an effective barrier against the passage of hydrogen.

As can be seen from FIG. 2, a second auxiliary material, namely an oxide layer 17 formed of for example of SiO₂, is applied to the construction illustrated in FIG. 1. The oxide layer 17 levels out the height differences caused by the islands 11 and the capacitor 5, 7, 9 and forms an essentially plane surface.

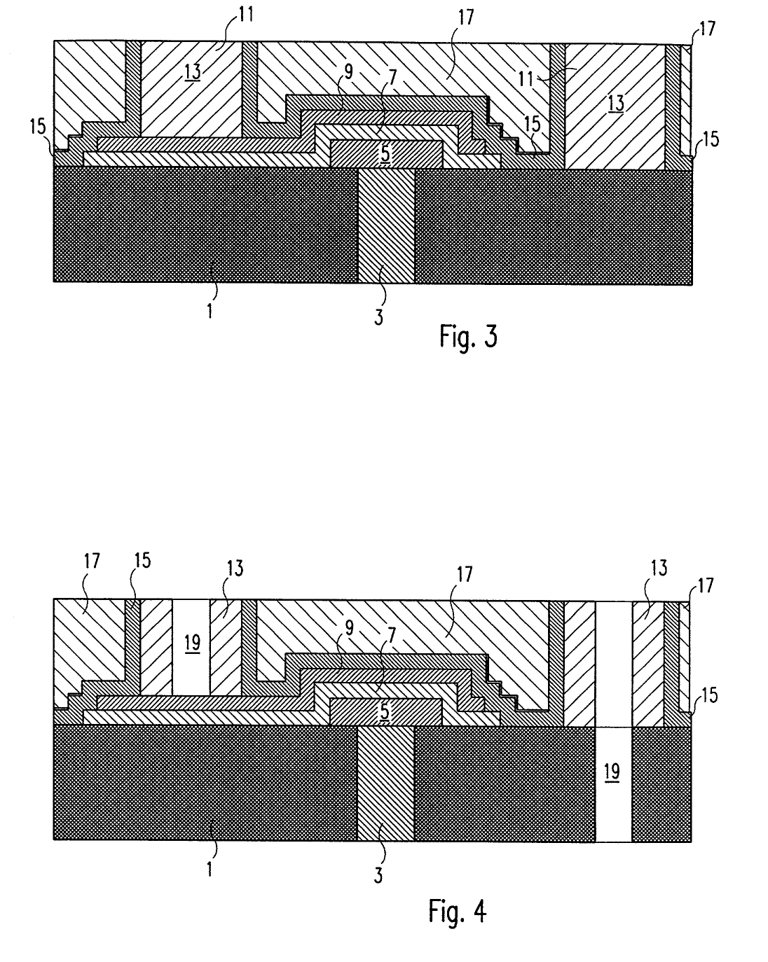

Material of the complete construction is now removed from the top by a chemical mechanical polishing (CMP) process. The etching plane thereby runs parallel to the surface plane of the oxide layer 17. During the course of the etching process, material is initially removed exclusively from the oxide layer 17, subsequently also material from the protective layer 15 in the region where the protective layer 15 forms a kind of cover for the island 11 illustrated on the left in FIG. 2, in further progression also material from the island 11 illustrated on the left in FIG. 2 and, in addition, material from the protective layer 15 where the protective layer 15 forms a cover on the island 11 illustrated on the right in FIG. 2. After the auxiliary material 13 is exposed of both the island 11 illustrated on the left and of the island 11 illustrated on the right, the etching process can be terminated. The aim of creating two window-like openings in the protective layer 15 has then been achieved (see FIG. 3).

Next, contact holes 19 are formed in the auxiliary material 13 in a region of the residual islands 11. The contact hole 19 illustrated on the left in FIG. 4 extends to the second electrode 9. The contact hole 19 illustrated on the right in FIG. 4 is a through-hole, which is driven on to the lower side of the substrate material 1. Subsequently the electrical contacting can be performed in a manner known in the prior art through filling the contact holes 19 and further contacting at a lower end of the through-hole 19.

In the exemplary embodiment described above the material of the layer 15 to be opened is an electrically insulating material. However, the invention is not limited to such materials. If the layer to be opened contains an electrically conductive material, in one variant of the method according to the invention an electrically insulating material is applied after the opening of the layer or after exposure of the auxiliary material—to the remaining material of the layer to be opened. This has the advantage that an unwanted electrical connection can be avoided between the layer to be opened and a superficial metallization layer yet to be applied. The electrically insulating material is preferably applied as a thin additional layer. In contrast to the material normally used for filling deeper-lying areas, a thin layer of this kind is not a hindrance during later etching of contact holes. The materials of the auxiliary structure and the insulating material applied to the remaining material of the layer to be opened are preferably chemically related or are the same material. In this case the respective hole in the additional insulating layer and in the material of the auxiliary structure can be etched in a single continuous etching step during the etching of contact holes. An etching process can also be used that exhibits high selectivity, i.e. that allows selective etching of the materials used or of one material.

The method according to the invention is also not limited to the application of island-like auxiliary structures. On the contrary, it is possible, for example, to apply an island-like auxiliary structure, however with an opening in its inner or central region. Such an auxiliary structure can, for example, be ring-shaped in cross-section. Auxiliary structures of this kind, and also island-like auxiliary structures, can be created in a single lithographic step with subsequent etching away of the superfluous material.

If an auxiliary structure of this kind contains an electrically insulating material and the layer to be opened contains an electrically conductive material, opening of the layer to be opened will result in the formation of at least two regions with the electrically conductive material which are mutually electrically insulated through the material of the auxiliary structure.

The above structure, in which two mutually electrically insulated regions of the layer to be opened exist is then especially advantageous if the layer to be opened acts as a hydrogen barrier, similar to that described with reference to the FIGS. 1 to 4. If the layer to be opened or the layer already opened by planar etching has an electrical contact to several electrodes, whereby each of the electrodes is assigned to a capacitor, it is necessary to prevent a short circuit between the electrodes. This is achieved in that each one of the electrically conductive hydrogen barrier regions that is electrically insulated against other regions is electrically connected with only one of the electrodes. If each of the electrodes is connected with an electrically conductive hydrogen barrier, the hydrogen barrier is electrically structured in a way corresponding to the electrodes of the capacitors in their entirety.

By the method according to the invention it is therefore possible first to apply one or several auxiliary structures of electrically insulating material, then to apply a continuous electrically conductive hydrogen barrier, and then through planar etching to open the hydrogen barrier in such a way that the required structure of the hydrogen barrier is produced with separated, mutually insulated regions.

In comparison with other methods for the creation of specific local openings in a layer, CMP has the advantage that greater rates of etching can be achieved. Moreover, the otherwise also usual planarization of the oxide layer 17 or a corresponding layer on a semiconductor component can also be used in an advantageous way in a single process step for opening the protective layer 15 or a corresponding layer. In addition, the contact holes 19 can be inserted in the auxiliary material 13 at a clear separation from the protective layer 15 so that the protective layer 15 outside the opened region is completely undamaged. Therefore overall, as demonstrated for the exemplary embodiment, it is possible to realize an effective barrier against the penetration of unwanted materials, for example hydrogen. Also, performance of the process, both during CMP and during the subsequent etching of contact holes, is relatively simple since it is not necessary to exercise absolute precision during etching, i.e. it is completely unnecessary to use masks (during CMP) and a relatively larger latitude is available for positioning the masks when etching the contact holes. Care must simply be taken when structuring the auxiliary structures, in the exemplary embodiment the islands 11, that the required position of the subsequent contact holes is defined, and care must be taken that the auxiliary structures at their edges, in the exemplary embodiment the edges running in a vertical direction, are adequately covered with the material of the protective layer 15.

The protective layer 15 or a corresponding layer must not necessarily be applied directly to the auxiliary structure. It is also possible to apply other materials to the auxiliary structure first, or to configure the entire construction in such a way that other materials are disposed, at least partially, between the material of the auxiliary structure and the layer to be opened.

We claim:

1. A method for precise local creation of openings in a structure, which comprises the steps of:
providing a substrate;
producing at least one raised auxiliary structure formed of an auxiliary material on the substrate such that the auxiliary structure covers a part of a surface of the substrate;
applying a layer, in which an opening is to be formed, to the auxiliary structure such that the layer covers a continuous region of the surface of the substrate and a surface of the auxiliary structure; and
using a planar etching process for removing part of a material forming the layer until the layer at the auxiliary structure is opened and the auxiliary material is exposed resulting in exposed auxiliary material.

2. The method according to claim 1, which comprises forming the auxiliary structure as an island-like elevation and that the material of the layer is removed in such a way that the layer forms a closed peripheral edge around the exposed auxiliary material.

3. The method according to claim 1, which comprises applying a further auxiliary material to the layer.

4. The method according to claim 1, which comprises performing the planar etching process as a chemical mechanical polishing process.

5. The method according to claim 1, which comprises etching an opening in the exposed auxiliary material of the auxiliary structure.

6. The method according to claim 5, which comprises:
applying an electrically conductive material on the substrate before performing the step of producing the auxiliary structure;
inserting a further electrically conductive material into the opening extending as far as the electrically conductive material.

7. The method according to claim 1, which comprises forming a microelectronic structure with a capacitor on the substrate before performing the step of producing the auxiliary structure, the capacitor has a dielectric formed of a material selected from the group consisting of ferroelectric materials and paraelectric materials and that the layer to be opened forms a barrier against a penetration of a substance into the microelectronic structure.

8. The method according to claim 7, wherein the dielectric is sensitive towards an effect of hydrogen and that the layer to be opened is a barrier against a penetration of the hydrogen into the dielectric.

9. The method according to claim 1, which comprises forming the layer to be opened of an electrically conductive material, and after exposure of the auxiliary material, an electrically insulating material is applied to remaining material of the layer to be opened.
